(19) United States
(12) Patent Application Publication
(10) Pub. No.: US 2024/0057303 A1
(43) Pub. Date: Feb. 15, 2024

(54) SEMICONDUCTOR COOLING ARRANGEMENT WITH IMPROVED HEATSINK

(71) Applicant: YASA LIMITED, Oxfordshire (GB)

(72) Inventors: Simon David HART, Powys (GB); Daniel RENDELL, Oxfordshire (GB); Paul Donald SPENDLEY, Oxfordshire (GB); Rajesh KUDIKALA, Berkshire (GB)

(21) Appl. No.: 18/269,486

(22) PCT Filed: Dec. 17, 2021
(86) PCT No.: PCT/EP2021/086627

§ 371 Date: Jun. 23, 2023

(30) Foreign Application Priority Data
Dec. 23, 2020 (GB) 2020546.4

(51) Int. Cl. H05K 7/20; H01L 23/473; H01L 23/44; H01L 23/00; H01L 21/56

(52) U.S. Cl. CPC H05K 7/20927; H01L 23/4735; H01L 23/44; H01L 24/29; H01L 24/83; H01L 24/32; H01L 21/56; H01L 23/3121

(57) ABSTRACT

The semiconductor cooling arrangement comprises one or more semiconductor assemblies, a housing, and one or more baffles. Each semiconductor assembly comprises a heatsink, a semiconductor die, an encapsulant, and electrical connections. The semiconductor die is bonded to the heatsink and contains a semiconductor power device. The encapsulant covers the semiconductor die. The side of the heatsink to which the semiconductor die is bonded extends beyond the encapsulant. The electrical connections pass through the encapsulant and to the semiconductor die. The housing has a chamber for housing the one or more assemblies. Each baffle comprises through-holes arranged such that fluid flows through the through-holes to a region of a respective semiconductor assembly to which the semiconductor power device is mounted, or to a region of the heatsink of the semiconductor assembly opposite a location to which the semiconductor power device is mounted.

### FIELD OF THE INVENTION

The present invention relates to a semiconductor cooling arrangement for cooling semiconductor devices, such as power semiconductors. Such arrangements are advantageous in the field of inverters due to the high power losses and associated heat generated by such devices.

### BACKGROUND

Electrical and electronic components generate heat as a by-product when they are in use. Overheating usually impacts performance and component lifetime and therefore electrical and particularly electronic components are typically cooled to prevent overheating.

Devices have limitations on the upper temperature at which they may be effectively operated and as limit temperatures are breached so devices may become less efficient and may fail. In most instances devices are unable to recover from failures due to overheating and the whole system in which they are a part becomes unusable, requiring repair or in many cases “burnt out” modules/systems are replaced.

Prevention being better than cure much effort has gone to making systems more robust, but ease of repair is also of value.

Many different approaches have been used to address overheating limitations: Some have sought to increase the operating limit of devices, though the scope for this is limited, whilst the majority of effort has been focused on removal of heat from devices, sub-modules and systems. In many power electronics applications, heatsinks are used where efficient heat dissipation is required. Heatsinks absorb and dissipate heat from electrical components by thermal contact. For example, a heatsink may be soldered, bonded or otherwise mounted to a power electronic device to improve heat removal by providing a large thermal capacity into which waste heat can flow.

In high power applications the heatsink may be enlarged to improve thermal capacity. However increasing the size of a heatsink increases the weight and volume of a power supply module and correspondingly the cost. In many instances the available space for such modules particularly for automotive applications is decreasing rather than the reverse.

Considerable effort has been applied to cooling of electronic components in computing systems wherein central processing units (CPUs) have many millions of semiconducting devices integrated onto the surface of a silicon die. Though heat loss from any one device is small, integration density has led to total heat dissipation being high and is a severe limitation on speed and lifetime of CPUs.

Some of the technologies for cooling electronic components in computing systems have also been applied in cooling of high power single or low level integration semiconducting switch devices.

In US2011/103019 there is described a liquid tight enclosure providing immersion cooling of an electronic system in which a cold plate is proposed having a liquid conduit for supplying coolant to the cold plate, said cold plate having a bottom surface coupled to an electronic component of the electric system and at least one open port on the side walls. In a particular embodiment coolant supplied by a conduit enters the top of the cooling plate and is partially allowed to exit through side ports, whilst remaining coolant is caused to flow through jets directed onto high heat flux components: Side port apertures and jet orifices being dimensioned to provide optimised cooling of components.

US2011/103019 is particularly directed towards cooling of CPUs in computers and describes cooling of a high powered processor chip mounted on a substrate said substrate being electrically and mechanically attached to a processor module which is further attached to a printed circuit board.

A disadvantage of US2011/103019 is poor heat spreading through said substrate and particularly poor heat spreading through connections to said printed circuit board.

For medium power converter modules there is another order of power dissipation to contend with, currents of 100's of amps and voltages of the order of 1000V in play. For medium power converters semiconducting switch devices are used and US2011/0242760 teaches an arrangement wherein semiconducting switch devices are mounted on laminated busbars so as to maintain electrical isolation between phases. Prior to US2011/0242760 said lamination in busbars would have been a temperature limiting feature, whereas US2011/0242760 teaches applying a liquid cooled heatsink to the said laminated busbars wherein the heatsink is electrically isolated from the busbar. Removal of heat from busbars and by thermal conduction from electrically isolated switch devices mounted thereon improves overall power capacity, before temperature rise and thermal limitation of insulation layers is again a limiting factor.

US2014204532 provides an alternate mode of cooling of heat dissipating semiconducting devices using impingement jets wherein application of jet cooling (air, or liquid in an air matrix) is controlled locally by thermally deformable nozzles made from shape memory alloy which is thermally connected to semiconducting devices to be cooled. In this way devices may be cooled when required. However US2014204532 is directed towards chip level cooling with impingement jets focused on backside of flip-chips. Teaching of US2014204532 is to liquid-in-air jets and is thereby limited in its cooling capacity and because cooling is at chip scale, pinout configurations further limit the connectivity of such cooling arrangements.

US2011141690 speaks to the use of a high thermally conductive printed circuit board substrate on one side of which is configured into the surface, features to promote turbulence in an impinging coolant flow whilst the other side of the circuit is configured to have electrical circuitry onto which are mounted power electronic components, for instance components of a power inverter module for use in a vehicle. The electrical circuitry side is electrically isolated from the side configured to promote turbulence.

Substrates such as direct bonded copper or direct bonded aluminium are suggested which comprise a ceramic (usually alumina) sandwich with copper or aluminium outer layers. However though these direct bonded substrates are good thermal conductors they are also expensive to manufacture and difficult to handle and carry out repairs.

Other approaches for improved cooling of power semiconducting devices include direct immersion of components in dielectric fluids and configuring of components to form coolant channels, use of phase change liquid/gas coolant systems to increase coolant effect.

In combination with these approaches particularly for power electronic systems has been optimisation of switching speed of power semiconducting switch devices: Reasoning for this is as follows—the faster the switch speed the less time the switch device spends in resistive mode and hence less joule heating losses in the device—however fast switching speeds increase inductive losses which may also lead to voltage spikes, hence a need for large low inductance busbars and symmetric phase legs in inverter modules and costly overvoltage specified capacitors.

A compromise is reached which inevitably leads to joule heating losses in semiconducting device switches. Despite best attempts all cooling approaches to date have been deficient in their cooling abilities and cooling efficiency of power semiconductor components has been a limiting feature of maximum power handling and power density for power semiconducting switch devices and hence power inverters.

The present invention seeks to increase the power density and maximum power handling of power inverters and semiconducting switch devices respectively, by significantly improving removal of waste heat and at the same time further reducing system wide inductance and corresponding joule heating losses in semiconducting switch devices.

We have therefore appreciated the need for an improved cooling arrangement.

### SUMMARY

According to a first aspect of the present invention, there is provided a semiconductor cooling arrangement. The semiconductor cooling arrangement comprises one or more semiconductor assemblies, a housing, and one or more baffles. Each semiconductor assembly comprises a heatsink, a semiconductor die, an encapsulant, and electrical connections. The semiconductor die is bonded to the heatsink and contains a semiconductor power device. The encapsulant covers the semiconductor die. The side of the heatsink to which the semiconductor die is bonded extends beyond the encapsulant. The electrical connections pass through the encapsulant and to the semiconductor die. The housing is for housing the one or more assemblies in a chamber within the housing, and comprises inlet and outlet ports in fluid communication with the chamber. Each baffle comprises through-holes arranged such that fluid flows through the through-holes to a region of a respective semiconductor assembly to which the semiconductor power device is mounted, or to a region of the heatsink of the semiconductor assembly opposite a location to which the semiconductor power device is mounted.

According to a second aspect, there is provided a semiconductor cooling arrangement. The semiconductor cooling arrangement comprises a semiconductor assembly and a coolant channel. The semiconductor assembly comprises a heatsink, a semiconductor die, an encapsulant, and electrical connections. The semiconductor die is bonded to the heatsink, and contains a semiconductor power device. The encapsulant covers the semiconductor die. The side of the heatsink to which the semiconductor die is bonded extends beyond the encapsulant. The electrical connections pass through the encapsulant and to the semiconductor die. The coolant channel is located on a side of the heatsink opposite the bonding location of the semiconductor die.

According to a third aspect, there is provided a method of manufacturing a semiconductor assembly. A heatsink is provided. A semiconductor die is bonded to the heatsink, the semiconductor die comprising a transistor. Electrical connections are connected to the semiconductor die. The semiconductor die is encapsulated using an encapsulant, such that the electrical connections protrude from the encapsulant and the encapsulant covers only a portion of the side of the heatsink to which the die is bonded.

Further embodiments of the invention are presented in claim 2 et seq.

### BRIEF DESCRIPTION OF THE DRAWINGS

FIG. 1 is a system block diagram of a power supply for a motor;

FIG. 2 shows a typical package for a semiconductor power device;

FIG. 3 shows a cutaway view of a particular implementation of a cooling system;

FIG. 4 shows an alternative implementation of a cooling system;

FIG. 5 shows an arrangement for a semiconductor assembly;

FIG. 6 shows a structure for a heatsink;

FIG. 7 shows the process of assembling a semiconductor assembly using the heatsink of FIG. 6;

FIG. 8A shows the reverse of a heatsink;

FIG. 8B is a diagram depicting raised features of the heatsink of FIG. 8A;

FIG. 9A shows a support structure;

FIG. 9B shows the locking lugs used in FIG. 9A;

FIGS. 10A, 10B, and 100 show various possible arrangements of through-holes on a baffle;

FIG. 11 shows a PCB baffle;

FIG. 12 is a system block diagram showing which components may be included on the PCB baffle.

### DETAILED DESCRIPTION

Several proposals will be described herein for improvements relating to cooling a semiconductor assembly, each in their own section—though it will be appreciated that these improvements may be combined in appropriate ways as described in the below description and otherwise, or used separately. For the assistance of the coming description, a base device will first be described, without any of the individual improvements.

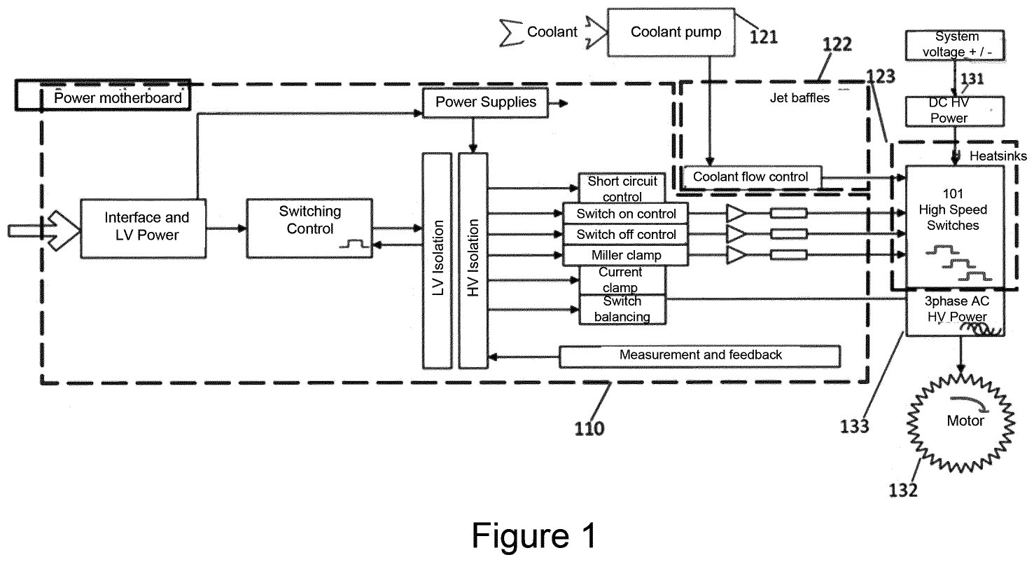

FIG. 1 is a system block diagram of a power supply for a motor, the power supply comprising a switching device, with dashed boxes showing the locations of individual components or subsystems. The switching device comprises:
a motherboard 110 containing switching control circuitry;
a cooling system comprising a cooling pump 121, baffles 122 or other coolant flow control elements, and a heatsinks 123;
semiconductor assemblies comprising semiconductor power devices such as high speed switches 101 mounted on (or otherwise thermally coupled to) the heatsinks 123. Each heatsink 123 may have one or more high speed switches mounted to it.

The cooling system and semiconductor assemblies together form a semiconductor cooling arrangement.

The switching device controls the flow of power from a DC high voltage power supply 131 to a motor 132, via conversion to 3 phase AC power 133.

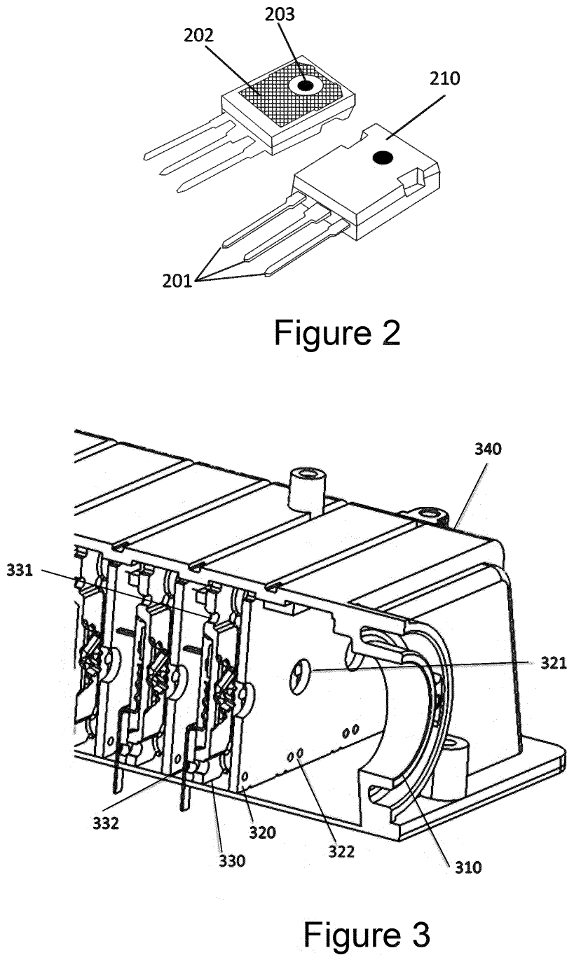

FIG. 2 shows a typical package for a semiconductor power device, e.g. the switches 101 of FIG. 1 (in this case, a 3-pin insulated gate bipolar transistor switch (IGBT)), diodes, or similar components. The package 210 is a polymer casing containing a silicon die on which the transistor is located, and further comprises electrical contacts 201 corresponding to the inputs and outputs of the semiconductor power device (e.g. the base, collector, and emitter or gate, source, and drain of a transistor). Such a package also commonly includes a heatsink base plate 202 to provide a thermal connection between the silicon die and external cooling means such as a heatsink, e.g. by soldering. The heatsink base plate may be electrically connected to one of the inputs or outputs of the semiconductor power device, e.g. the drain of a transistor. The package may also have a mounting hole 203 to allow it to be mounted via a screw, rivet, or other similar attachment.

FIG. 3 shows a cutaway view of a particular implementation of cooling system, and in particular the baffles 122 and heatsinks 123 of FIG. 1. The cooling system comprises a coolant input 310, a plurality of baffles 320, and a plurality of heatsinks 330, arranged within a coolant channel 340. This description assumes that coolant flow in the figure is from right to left, though it may also be the other way around (with the coolant input 310 being a coolant output). Directions within the coolant channel may be described as “upflow” (i.e. towards the coolant input) or “downflow” (i.e. towards the coolant output).

Each baffle 320 has a plurality of through-holes 321, positioned such that coolant flowing through those through-holes 321 will strike the heatsink as a jet, on regions of the heatsink opposite the mounting location of each semiconductor power device. There may be a set of circular through-holes for each semiconductor power device, as shown in the figure, or other numbers, shapes, and distributions of through-holes. Additional through-holes 322 may be provided to cool further components, e.g. in this case the through-holes 322 are positioned to cool the high voltage connections to the semiconductor power devices.

Each heatsink 330 has one or more semiconductor power devices mounted to it (on the reverse side, as viewed in the Figure), and a plurality of through-holes 331 surrounding the mounting location of the semiconductor power device, which direct coolant to the next baffle. Each heatsink may have additional through-holes 332 corresponding to the additional through-holes 322 on each baffle.

As an alternative to through-holes 331, 332, each heatsink may extend only partially across the coolant channel, allowing coolant to flow around the edges of the heatsink.

The coolant channel 340 encloses the heatsinks 330 and the baffles 320, such that each heatsink and baffle extends across the coolant channel. Coolant provided via the coolant input 310 then flows through each baffle, creating jets on each heatsink and providing cooling, then through the heatsink to the next baffle, mixing turbulently in the space between the heatsink and the baffle (both ensuring mixing of the fluid, and providing additional cooling to the semiconductor power device package). While the figure shows two heatsinks and two baffles, it will be appreciated that this pattern can be repeated for any number of heatsinks and baffles, and similarly that each heatsink may have mounting locations for any number of semiconductor power devices.

The coolant provided to the coolant input 310 is a coolant with very low electrical conductivity, e.g. a dielectric coolant. Optionally, additional flow guides (not shown) may be provided between baffles 320 and heatsinks 330 to direct fluid flow between the respective through-holes.

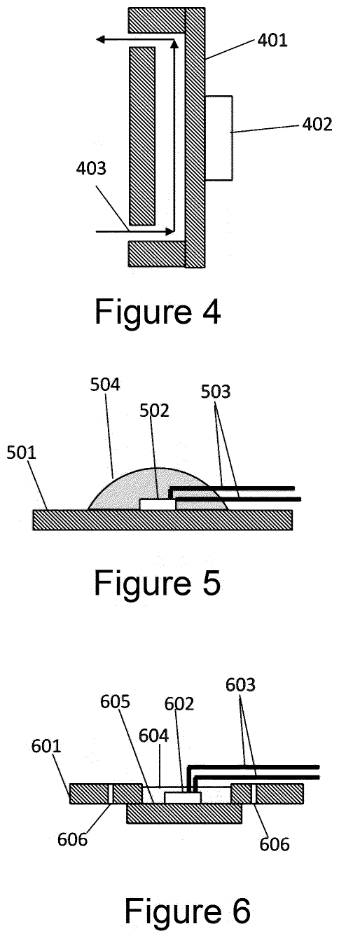

FIG. 4 shows an alternative implementation of a cooling system, for “one-sided” cooling of the heatsink. The heatsink 401 has a semiconductor power device 402 mounted thereon. On the opposite side of the heatsink 401, there is a coolant channel 403, configured to cause coolant to flow across the heatsink. This arrangement cools the heatsink without allowing electrical contact between the coolant and the semiconductor power device 402 or its electrical connections (except perhaps a single connection via the heatsink). As such, this arrangement allows for the use of coolants that have higher electrical conductivity, such as water. Again, this arrangement may comprise additional flow guides to direct fluid over the heatsink.

1. Die on Heatsink

a. Direct Die Bond

An issue with the package design shown in FIG. 2 is that the only effective way to get heat out from the die is via the heatsink base plate 202, as the package is typically made from a material with relatively low thermal conductivity. For high-power semiconductor assemblies, this can be a significant barrier to effectively cooling the die.

An alternative arrangement is shown in FIG. 5. The heatsink 501 is bonded directly to the die 502 which contains the semiconductor power device itself, without an intervening package as described with reference to FIG. 2. Electrical connections 503 are then provided from the die—as previously, one of these (e.g. the source or drain) may be via the heatsink. The electrical connections 503 may then be connected to the motherboard of the switching device. The die is encapsulated with an insulating material 504, e.g. an epoxy resin.

PCB elements may be provided for the electrical connections, e.g. to provide structural stability compared to bare copper, or to separate them from the heatsink. The electrical connections may be insulated from the heatsink by providing a gap underneath them which the encapsulant will fill. Further connections, e.g. a thermally conductive connection for use with a temperature sensor, may be provided.

The structure of the heatsink surrounding the die may be any desired structure—e.g. equivalent to those described with reference to FIG. 3 or 4 above, or having one or more of the heatsink features described later in this document.

The process of assembling the assembly is summarised below:
1. The die 502 is bonded to the heatsink 501.
2. Electrical connections 503 are connected to the die 502.
3. Encapsulant 504 is applied to encapsulate the die.

The die may be bonded to the heatsink by sintering. The sintering may be performed by applying a layer of a fusible/sinterable, generally high thermally conductive material (e.g. silver, copper, nickel, gold, or a solder) to the heatsink, and then sintering the die to that layer. The layer may be applied in, for example, tape/film, powder or paste formats, if applied as a separate material, or can be applied as a wafer backside coating. Alternatively, the die may be bonded to the heatsink by soldering or the use of an adhesive.

Applying the encapsulant may comprise applying a barrier around the die to define the extent of the encapsulant, and then filling the region within that barrier with encapsulant. The barrier may be removable, or may be allowed to remain attached to the heatsink.

The connections 503 will also act to bring heat out of the die through the encapsulant, aiding the heatsink 501 in cooling the die, as the encapsulant will generally be less thermally conductive than connections 503 or heatsink 501.

b. “Bathtub” Heatsink Structure

FIG. 6 shows a heatsink structure particularly suited to the “direct die bond” described in section 1a. This heatsink structure is referred to as a “bathtub” heatsink structure. The heatsink 601 has a semiconductor die 602 bonded to it, which contains a semiconductor power device, as before, and the die has electrical connections 603. In contrast to the assembly shown in FIG. 5, the heatsink has a recess 605 (also known as a blind hole or well), and the die is bonded to the heatsink at the base of that well. The encapsulant 604 is then provided within the recess. The heatsink may comprise through-holes 606 surrounding the recess, which correspond to the through-holes 331 of the heatsink of FIG. 3.

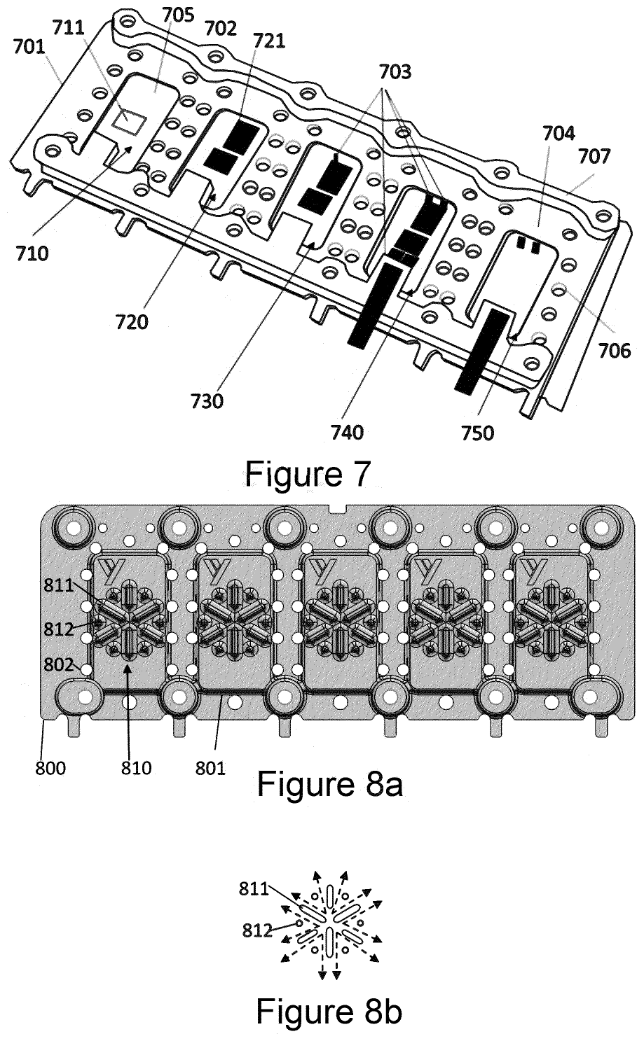

The process of assembling the assembly using the bathtub heatsink structure is shown in FIG. 7.

In step 710, the heatsink 701 is prepared for bonding with the semiconductor power device die 702. As an example, this may comprise applying a patch 711 for bonding of the semiconductor power device die within the recess 705.

In step 720, the semiconductor power device die 702 is bonded to the heatsink 701, e.g. by sintering. If PCB elements 721 are used for any of the electrical inputs for the die, then these are also bonded to the PCB.

In steps 730 and 740, electrical connections 703 are attached to the semiconductor power device die 702 and PCB element 721, so that these can be accessed after encapsulation.

In step 750, encapsulant 704, e.g. epoxy, is provided within the recess. The encapsulant may fill the recess, i.e. being flush with the heatsink around the recess, or it may only partially fill the recess to a depth sufficient to cover the die.

In contrast to the method described for a flat heatsink in the previous section, no barrier is required to contain the encapsulant when it is applied, which simplifies manufacture of the assembly and reduces the possibility for encapsulant leaking beyond the desired region.

FIG. 7 also shows through-holes 706, as described previously, and support structures 707, which elevate the electrical connections 703 and provide spacing between the heatsink and the adjacent baffle. Individual features of the support structures are described in more detail later, but it will be appreciated that any suitable support structure may be used with the features described in this section.

The heatsink 701 may comprised protrusions within the recess to aid in the alignment of the die and/or any PCB elements.

2. Improved Heatsink Structure

a. Baffle-Heatsink Assembly with Integrated Fluid Guidance on Heatsink

FIG. 8A shows one side of a heatsink 800 (the side opposite the side to which the semiconductor power device is attached). Heatsink 800 is shown with recess 801 and through-holes 802, but it will be appreciated that recess 801 (as described in section 1b) is not required for the feature described in this section. Heatsink 800 has raised features 810 integral to the heatsink and arranged in a “snowflake” pattern which is reproduced in simplified form in FIG. 8B. The raised features 810 comprise both elongate 811 and circular 812 protrusions, and, when a jet of coolant impinges against the heatsink (i.e. a jet from a baffle, as described with reference to FIG. 3), the raised features act to direct the flow of coolant towards the through-holes 802 as shown by the arrows in FIG. 8B. In addition, the raised features increase the surface area of the heatsink, which together with the improved flow will increase the cooling of the heatsink. For avoidance of doubt features 810 are raised and are not caused by indenting the reverse side which may remain flat (or have any other desired features, e.g. a recess as described previously).

The arrangement of raised features 810 is suitable for a baffle which causes jets to impact within the area of the “snowflake”. Alternative patterns of raised features may be used, and these may be optimised for particular arrangements of jets from the baffle (i.e. through-holes on the baffle) or through-holes on the heatsink. In general, the features are arranged to promote flow from the jet impact region to the through-holes on the heatsink. Otherwise, impinged fluid from the jet can prevent additional fluid from the jet from hitting the surface.

b. Support Structure Connecting Baffle and Heatsink

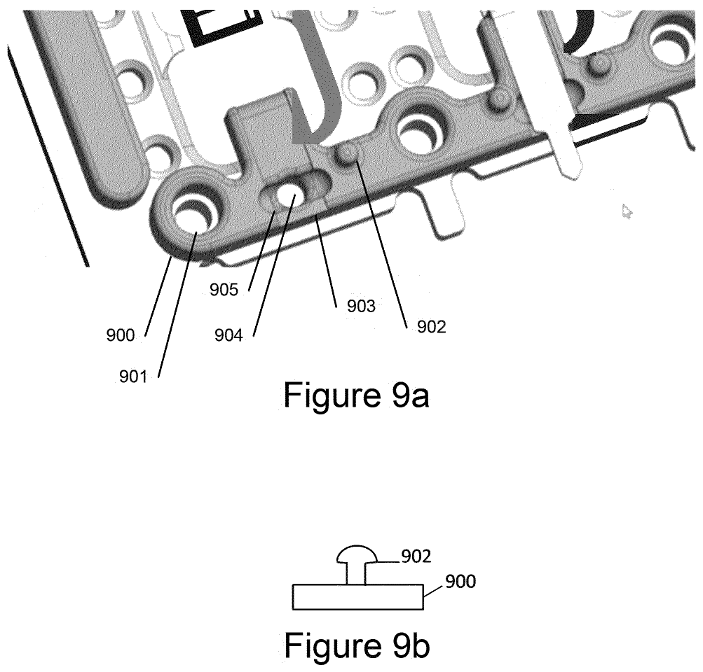

FIG. 9A is a close-up of the support structure shown in FIG. 7. The support structure acts to space out each heatsink from the adjacent baffle, on the side of the heatsink where coolant flows from the heatsink to the next baffle. The reason for this spacing is to allow a chamber for turbulent mixing of the fluid after it has passed through the heatsink. On the side where the fluid flows from the baffle to the heatsink, a chamber with a lower width is desirable, to ensure that the jets formed by the baffle impact the heatsink (or encapsulant, depending on flow direction).

In the example shown in FIG. 9A, the chamber for turbulent mixing is on the same side of the heatsink as the semiconductor power device. The support structure 900 comprises fixing holes 901 which line up with corresponding holes on the heatsink and baffle, and allow the cooling assembly to be fastened together by bolts, rods, or similar means. The support structure may also comprise locking lugs 902, shown in profile in FIG. 9B, which act to fasten the support structure to the baffle, along with additional through-holes provided in the baffle which line up with the lugs.

The support structure may also comprise a plurality of channels 903 for the electrical connections to the semiconductor power device to pass through. The channels may extend over the heatsink to the semiconductor power device, allowing the electrical connection(s) to be easily isolated from the heatsink. The channels may each include a through-hole 904 allowing fluid flow through the additional through-holes on the heatsink (e.g. as in FIG. 3, 332) to form a jet and impact the electrical connection. This additional cooling is particularly important where the electrical connection is, e.g. the source and is carrying high current. The support structure comprises a side channel 905 for each of the through-holes 904, to direct fluid flow around the electrical connections after impact of the jet, and towards the additional through-holes in the baffle (e.g. as in FIG. 3, 322).

c. Alternative Baffle Hole Arrangements

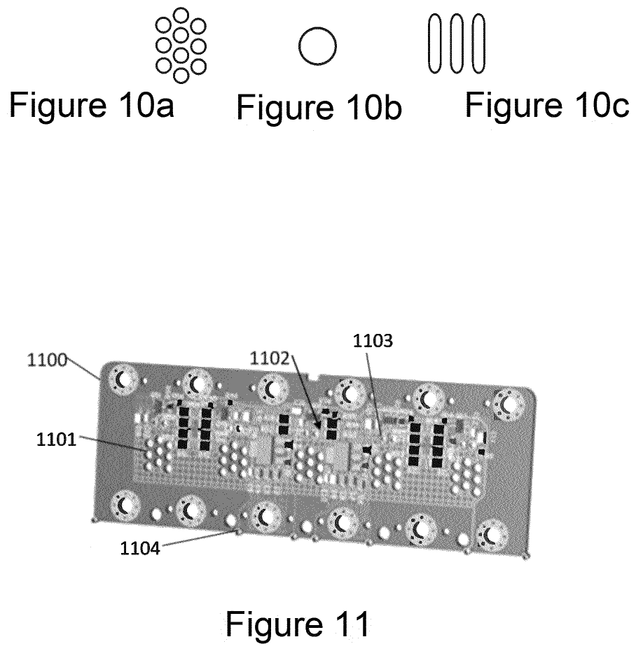

10 FIGS. 10A through 100 show various possible arrangements of through-holes on a baffle for providing coolant jets to the heatsink, all to approximately similar scale. As can be seen from the variety of patterns, there is significant scope for different designs which may be optimised based on desired fluid flow and fluid pressure through the coolant channel. The pattern of through-holes may be different for different baffles within the coolant channel, or for different patterns on the same baffle, e.g. to account for pressure losses through the coolant channel.

3. Integrated Baffle and PCB

a. Control Electronics on Baffle Assembly

A major disadvantage of existing designs is that the cooling required to maintain appropriate temperature on high power, high speed switches or other semiconductor power devices takes up significant space, and this results in the semiconductor power devices being further away from the motherboard. This increased distance reduces the efficiency of the switching control and power delivery circuitry, resulting in greater heat generation and greater electromagnetic interference from the switching device as a whole.

FIG. 11 shows a potential solution to this issue. FIG. 11 depicts a baffle 1100 which may be used similarly to the baffles in FIG. 3. As with the baffles in FIG. 3, the baffle 1100 has through-holes 1101 to direct coolant to a heatsink (not shown). The baffle 1100 is constructed as a PCB which also contains a portion of the switching control circuitry 1102. Other than the need to provide through-holes 1101, the circuitry on the PCB may be arranged as per normal PCB design principles.

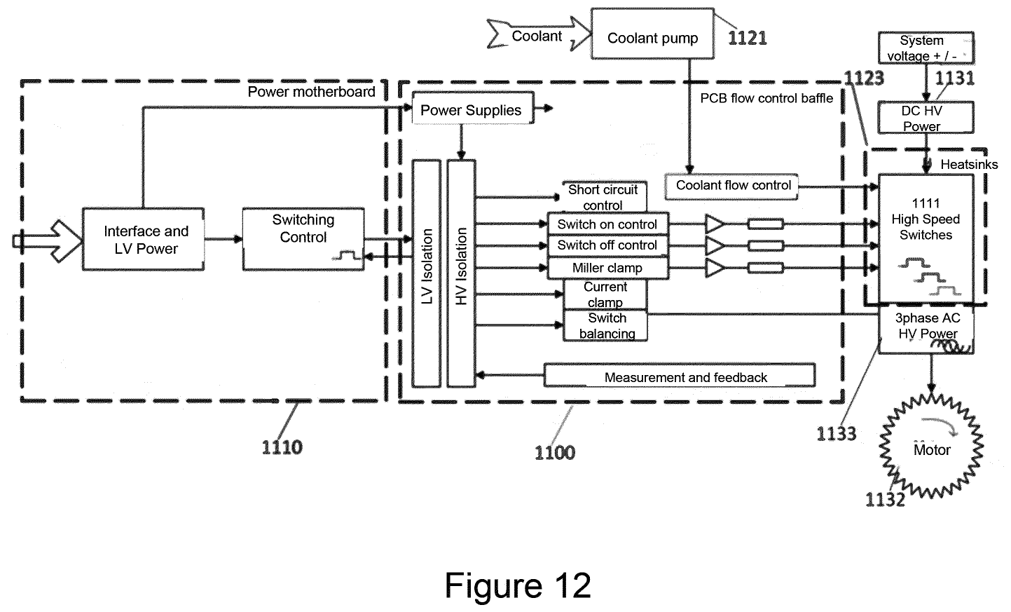

FIG. 12 is a system block diagram, similar to FIG. 1, showing which components may be provided on the PCB baffle 1100, and which should still be provided on the motherboard 1110. The high voltage DC power delivery 1131, the heatsink 1123 with attached switches 1111, the 3 phase power supply 1133, the coolant pump 1121 and the motor 1132 are not affected by this rearrangement, except in certain examples as noted below.

In general, the PCB baffle may contain circuitry for:
Isolation of high voltage and low voltage components,
Logic,
Local gate buffering;
Resistances or impedances required for gate control;
Local current balancing;
Miller clamping;
Fast overcurrent protection.

Including the gate resistors for a transistor on the PCB baffle provides a significant advantage to efficiency. Further advantages are provided by the inclusion on the PCB baffle of Miller clamps, gate buffers, and buffer caps. Other components listed above are advantageous to include, but to a lesser extent.

Components on the PCB may include simple electronic components (resistors, capacitors, inductors, etc), integrated circuits (including application specific integrated circuits, ASICs), terminals or other attachment points 1103 for connection to the semiconductor power devices and terminals or other attachment points 1104 for connection to the motherboard.

When using a PCB baffle, electrical contact between the PCB and the gate may be made across the coolant chamber formed between the PCB and the heatsink. Similarly, connection may be made across the coolant chamber between the PCB and the semiconductor power device for temperature sensing or similar.

The PCB baffle may be connected electrically to the semiconductor power devices on its downflow side, on its upflow side, or on both sides. The PCB baffle may be connected through the encapsulant, or vias through the heatsink may be provided for electrical connections to the PCB baffle if it is on the side of the heatsink opposite the semiconductor power device.

In general, where another section of this document refers to providing through-holes in a baffle, or other structural features of a baffle, these may be applied to the PCB baffle with appropriate routing of the electronics on the PCB.

4. Additional Combinations and Synergies

a. Manufacturing Method for Heatsinks

Heatsinks according to the general disclosure at the start of the description, having a recess as described in section 1b, and/or having integrated fluid guidance as described in section 2a may be easily manufactured by stamping. In particular, by providing appropriate stamping dies, through-holes may be provided around the bonding location for the semiconductor power device, the recess may be formed, and/or the protrusions for integrated fluid guidance may be formed. In addition, the stamping method allows control of the thickness of the heatsink in specific areas, giving a large degree of control of the thermal properties while still allowing high-volume manufacturing to be performed easily.

b. Connecting “Die on Heatsink” to “PCB Baffle”

Where the die is directly bonded to the heatsink (as in section 1a), and the baffle is provided as a PCB with control electronics included (as in section 3a), connection may be made between the die and the PCB as necessary by providing electrical connections which stick up from the encapsulant and protrude towards the baffle. This is of particular use for the electrical connection to the gate of the transistor (which will generally be controlled by control circuitry on the PCB) and for temperature sensing (either by connection to a temperature sensor within the encapsulant, or by providing a thermally conductive protrusion which can be used to determine the temperature with sensors on the PCB).

1. A semiconductor cooling arrangement, the semiconductor cooling arrangement comprising:
one or more semiconductor assemblies, each semiconductor assembly comprising:
a heatsink;
a semiconductor die bonded to the heatsink, the semiconductor die containing a semiconductor power device;
an encapsulant covering the semiconductor die, wherein the side of the heatsink to which the semiconductor die is bonded extends beyond the encapsulant; and
electrical connections passing through the encapsulant and to the semiconductor die;
a housing for housing the one or more assemblies in a chamber within the housing, the housing comprising inlet and outlet ports in fluid communication with the chamber; and
a one or more baffles, each baffle comprising through-holes arranged such that fluid flows through the through-holes to a region of a respective semiconductor assembly to which the semiconductor power device is mounted, or to a region of the heatsink of the semiconductor assembly opposite a location to which the semiconductor power device is mounted.

2. The semiconductor cooling arrangement according to claim 1, wherein the semiconductor die is electrically coupled to the heatsink, and the heatsink acts as an electrical connection for one of:
the drain or source of the semiconductor power device, where the semiconductor power device is a transistor;
the collector or emitter of the semiconductor power device, where the semiconductor power device is a transistor;
the anode or cathode of the semiconductor power device, where the semiconductor power device is a diode.

3. The semiconductor cooling arrangement according to claim 1, wherein the semiconductor die is sintered to the heatsink.

4. The semiconductor cooling arrangement according to claim 3, wherein the heatsink comprises a silver layer, and the semiconductor die is sintered to the silver layer.

5. The semiconductor cooling arrangement according to claim 1, wherein the heatsink comprises a recess, the semiconductor die is bonded to the heatsink within that recess, and the encapsulant fills or partially fills the recess and does not extend beyond the recess.

6. The semiconductor cooling arrangement according to claim 1, wherein the semiconductor assembly comprises a plurality of semiconductor dies, each containing a transistor, and a plurality of respective regions of encapsulant, each region of encapsulant covering a respective semiconductor die and being separated from the other regions of encapsulant.

7. The semiconductor cooling arrangement according to claim 1, wherein the heatsink comprises a plurality of through-holes positioned around the encapsulant.

8. The semiconductor cooling arrangement according to claim 7, wherein the heatsink comprises a recess, the semiconductor die is bonded to the heatsink within that recess, and the encapsulant fills or partially fills the recess and does not extend beyond the recess, and wherein the plurality of through-holes are positioned around the recess.

9. The semiconductor cooling arrangement according to claim 7, and comprising a plurality of raised elements on the heatsink, opposite the bonding location of the semiconductor die, wherein the plurality of raised elements are arranged to guide fluid to the through-holes.

10. The semiconductor cooling arrangement according to claim 1, wherein the gap between each heatsink and the adjacent baffle in the direction of the outlet is larger than the gap between each heatsink and the other adjacent baffle in the direction of the inlet, other than for heatsink located closest to the outlet, and wherein the though hole of the adjacent baffle in the direction of the inlet is aligned with the encapsulant of each heatsink.

11. The semiconductor cooling arrangement according to claim 10, and comprising a support structure located between each heatsink and the adjacent baffle in the direction of the outlet.

12. The semiconductor cooling arrangement according to claim 11, wherein the support structure comprises a channel, and at least one of the electrical connections of each semiconductor assembly rests within the channel.

13. The semiconductor cooling arrangement according to claim 12, wherein the channel overlaps the encapsulant of the semiconductor assembly.

14. The semiconductor cooling arrangement according to claim 11, wherein the support structure comprises a though-hole aligned with the respective electrical connection, and the heatsink comprises a though-hole aligned with the through-hole of the support structure, and the channel is arranged to allow coolant to flow to the electrical connection via the through-hole and then around the electrical connection.

15. The semiconductor cooling arrangement according to claim 1, wherein each baffle comprises a through-hole aligned with one of the electrical connections of the semiconductor die.

16. A semiconductor cooling arrangement comprising:
a semiconductor assembly comprising:
a heatsink;
a semiconductor die bonded to the heatsink, the semiconductor die containing a semiconductor power device;
an encapsulant covering the semiconductor die, wherein the side of the heatsink to which the semiconductor die is bonded extends beyond the encapsulant; and
electrical connections passing through the encapsulant and to the semiconductor die; and
a coolant channel located on a side of the heatsink opposite the bonding location of the semiconductor die.

17. A method of manufacturing a semiconductor assembly, the method comprising:
providing a heatsink;
bonding a semiconductor die to the heatsink, the semiconductor die comprising a transistor;
connecting electrical connections to the semiconductor die;
encapsulating the semiconductor die using an encapsulant, such that the electrical connections protrude from the encapsulant and the encapsulant covers only a portion of the side of the heatsink to which the die is bonded.

18. The method according to claim 17, wherein the step of bonding comprises sintering the semiconductor die to the heatsink.

19. The method according to claim 18, wherein the heatsink comprises a silver layer, and the step of sintering the semiconductor die to the heatsink comprising sintering the semiconductor die to the silver layer.

20. The method according to claim 17, wherein the encapsulant is an epoxy resin.

21. The method according to claim 17, wherein the heatsink comprises one or more of:
through-holes through the heatsink;
a recess; and
raised elements opposite the bonding location of the semiconductor die;
and the step of providing the heatsink comprises stamping the heatsink from a metal blank.

22. The semiconductor cooling arrangement according to claim 12, wherein the support structure comprises a though-hole aligned with the respective electrical connection, and the heatsink comprises a though-hole aligned with the through-hole of the support structure, and the channel is arranged to allow coolant to flow to the electrical connection via the through-hole and then around the electrical connection.
